(19) United States
(12) Patent Application Publication
(10) Pub. No.: US 2023/0207345 A1
(43) Pub. Date: Jun. 29, 2023

(54) BASE PLATE FOR HEATER PEDESTAL

(71) Applicant: Applied Materials, Inc., Santa Clara, CA (US)

(72) Inventors: Muhannad Mustafa, Milpitas, CA (US); Mario D. Silvetti, Fountain Hills, AZ (US); Michael Jerry Duret, Pleasanton, CA (US); Sanjeev Baluja, Campbell, CA (US); Satish Radhakrishnan, San Jose, CA (US); Yuan Xiaoxiong, San Jose, CA (US)

(73) Assignee: Applied Materials, Inc., Santa Clara, CA (US)

(21) Appl. No.: 17/561,085

(22) Filed: Dec. 23, 2021

(51) Int. Cl. H01L 21/67; B23Q 1/03

(52) U.S. Cl. CPC H01L 21/67103; B23Q 1/032

(57) ABSTRACT

Embodiments of the disclosure advantageously provide base plates with decreased metal contamination. Some embodiments of the disclosure advantageously provide base plates with increased edge purge channel uniformity. Some embodiments provide methods of forming base plates. Embodiments of the disclose are directed to a heater pedestal configured to support a substrate during processing. In some embodiments, the heater pedestal includes the base plate described herein.

### TECHNICAL FIELD

Embodiments of the disclosure generally relate to base plates for heater pedestals. In particular, embodiments of the disclosure relate to base plates having decreased metal contamination and increased edge purge channel uniformity, and methods of manufacturing the same.

### BACKGROUND

Semiconductor processing chambers often contain a pedestal positioned in the chamber to support a wafer or substrate during processing. In many embodiments, the pedestal also contains a heater for maintaining the substrate at an elevated temperature during processing.

The pedestal also often contains several gas channels within the pedestal to aid in processing a substrate. For example, in some cases, the pedestal contains a vacuum channel which is used to secure the substrate to the pedestal. Another gas channel is an edge purge channel which provides a flow of purge gas to the region near the peripheral edge of the substrate to avoid unwanted deposition.

Conventional processes of forming edge purge channels include at least three steps. The first step includes a machining process to form one or more of a base plate and a heater plate. Edge purge channels are often formed in the base plate by the machining process. The second step is a lapping process, which includes rubbing together two surfaces (i.e., the surfaces of a base plate and a heater plate) with an abrasive between them. The third step is a high temperature, i.e., 2000° C., diffusion bonding process, which couples together or bonds the base plate and the heater plate on a heater pedestal. The lapping process and/or diffusion bonding process may result in contamination on the base plate, heater plate and substrate surface. Therefore, the lapping process and/or diffusion bonding process may result in contamination of the final product after processing.

Further, the edge purge channels are formed before the lapping and diffusion bonding processes. As a result, the final channels (after the lapping and diffusion bonding processes) often do not maintain the uniform size and/or shape with which they were formed by the machining process. These changes can result in each of the channels having different flow conductance resulting in the gas flow uniformity at the edge of the base plate being negatively affected.

Accordingly, there is a need for base plates with decreased metal contamination and/or increased edge purge channel uniformity as well as methods of forming these base plates.

### SUMMARY

One or more embodiments of the disclosure are directed to a base plate. The base plate comprises: a circular body having a top surface, a bottom surface, and an outer peripheral surface; and a plurality of substantially linear edge purge channels within the circular body. Each channel extends from the outer peripheral surface to a common point within the circular body. The base plate has an atomic copper level of less than or equal to 10×10¹⁰ atom/cm².

Additional embodiments of the disclosure are directed to a heater pedestal configured to support a substrate during processing. The heater pedestal comprises a base plate as described herein. Specifically, in some embodiments, the heater pedestal comprises a base plate having a circular body. The circular body has a top surface, a bottom surface, and an outer peripheral surface. The circular body also contains a plurality of substantially linear edge purge channels within the circular body. Each channel within the circular body extends from the outer peripheral surface to a common point within the circular body. The base plate of the heater pedestal has an atomic copper level of less than or equal to 10×10¹⁰ atom/cm².

Further embodiments of the disclosure are directed to a method of forming a base plate for a heater pedestal. The method comprises drilling a plurality of edge purge channels into an outer peripheral surface of a circular body of the base plate. The plurality of edge purge channels extend from the outer peripheral surface to a common point within the circular body.

### BRIEF DESCRIPTION OF THE DRAWINGS

So that the features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a side view of a heater pedestal according to one or more embodiment of the disclosure; and

FIG. 2 is a top view of a base plate according to one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates.

The term “on” indicates that there is direct contact between elements. The term “directly on” indicates that there is direct contact between elements with no intervening elements.

Throughout the disclosure, reference will be made to a measure of non-uniformity referred to as 3-sigma. A 3-sigma value denotes the percentage of measured points which fall outside of 3 standard deviations from the mean. Accordingly, a lower 3-sigma value corresponds to higher uniformity and lower non-uniformity.

One or more embodiments of the disclosure are directed to a heater pedestal. Some embodiments of the disclosure advantageously provide base plates with decreased metal contamination. Some embodiments of the disclosure advantageously provide base plates with increased edge purge channel uniformity. Some embodiments provide methods of forming base plates.

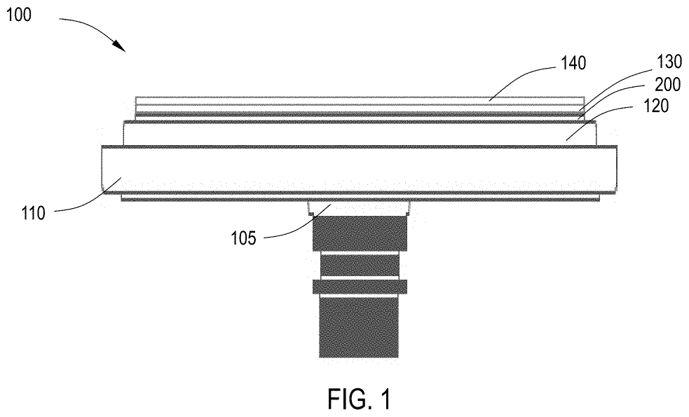

FIG. 1 illustrates a heater pedestal 100. The heater pedestal 100 is configured to support a substrate 140 during processing. In some embodiments, the heater pedestal 100 comprises a shaft 105 connected to a support base 110. A heater plate 120 is positioned on the support base 110. A base plate 200, as further described below, is positioned on the heater plate 120. A top plate 130 is positioned on the base plate 200. While each of the shaft 105, support base 110, base plate 200, heater plate 120 and top plate 130 are shown to be separate in FIG. 1, one skilled in the art would understand that these elements may be formed of the same material and one or more of these elements may be integrally formed together. The substrate 140 may be positioned on the top plate 130.

The shaft 105 provides a conduit for gas flows (e.g., purge, vacuum), electrical connections (e.g., heater power, metrology sensors, etc.), and mechanical connections (e.g., motor connections, structural support).

The support base 110 is connected to the shaft 105 and provides structural support for the heater plate 120, base plate 200, top plate 130, and substrate 140. In one or more embodiments, the support base 110 is configured as an electrostatic chuck. In some embodiments, one or more electrodes are within the shaft 105 thickness and are configured to form an electrostatic chuck. In some embodiments, the one or more electrodes are located at an electrode depth (not shown) from a bottom surface of the support base 110. In some embodiments, the one or more electrodes are configured as a monopolar electrostatic chuck. In some embodiments, the one or more electrodes are configured as a bipolar electrostatic chuck. The one or more electrodes can be connected to one or more power supplies (not shown) to polarize the electrodes to act as an electrostatic chuck.

The heater plate 120 comprises one or more heaters to maintain a supported substrate 140 at a fixed temperature during processing. In one or more embodiments, the heater plate 120 comprises one heating element. In some embodiments, the heater plate 120 comprises more than one heating element. In some embodiments, the more than one heating element are arranged concentrically so that one or more heaters operates primarily on an inner region of the substrate while an additional one or more heaters operates on an outer or peripheral region of the substrate 140. In some embodiments, the heater plate 120 contains two heating elements.

In an un-illustrated embodiment, the top plate 130 contains a vacuum channel within the top plate 130. The vacuum channel begins near the center of the top plate 130. In some embodiments, the vacuum channel begins at a predetermined point and continues to four outlets from which it flows to an external channel to chuck the substrate 140 to the top plate 130.

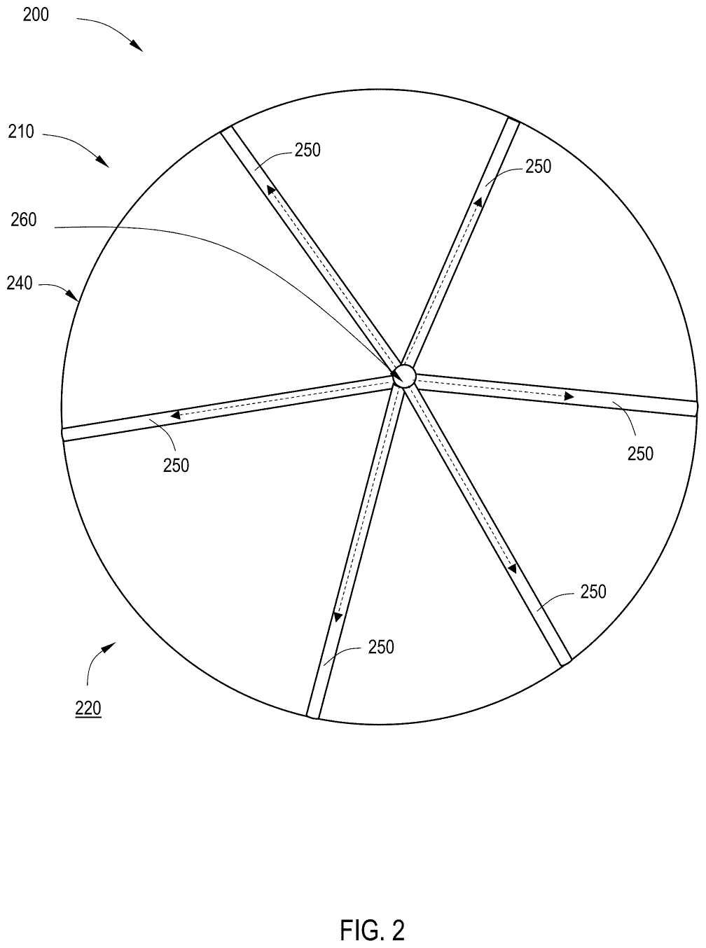

FIG. 2 illustrates a top view of a base plate 200. In one or more embodiments, the heater pedestal 100 comprises the base plate 200. In some embodiments, the base plate 200 comprises a circular body 210 having a top surface 220, a bottom surface (not shown), and an outer peripheral surface 240. The circular body 210 has a horizontal cross-section that is circular in shape. In some embodiments, the circular body 210 has a cylindrical shape. For the avoidance of doubt, a cylindrical shape would include right angles between the top surface 220 and the outer peripheral surface 240, and the bottom surface and the outer peripheral surface 240. In some embodiments, the outer peripheral surface 240 is curved or slanted relative to the top surface 220 and/or the bottom surface. In some embodiments, the circular body 210 has the shape of a frustum. In some embodiments, the outer peripheral surface 240 may be convex or concave.

In some embodiments, the base plate 200 comprises a plurality of substantially linear edge purge channels 250 within the circular body 210. Each channel 250 extends from the outer peripheral surface 240 to a common point 260 within the circular body 210. As used in this regard, “substantially linear” means that each channel 250 is has less than a 10%, 5%, 3%, or 1% deviation in linearity of each channel 250 over its entire length.

In some embodiments, the common point 260 is within a region bounded by a circle with a radius of less than or equal to 15% of a total radius of the circular body 210. In some embodiments, the common point 260 is within a region bounded by a circle with a radius of less than or equal to 10%, less than or equal to 5%, less than or equal to 2% or less than or equal to 1% of a total radius of the circular body 210. In one or more embodiments, the common point is at the center (the horizontal center) of the circular body 210. As used in this specification and the appended claims, “the center of the circular body” refers to the center of the circular horizontal cross-section of the circular body 210.

In some embodiments, a cross-section of one or more of the plurality of edge purge channels 250 is circular. In some embodiments, a cross-section of one of the plurality of edge purge channels 250 is circular. In some embodiments, each edge purge channel 250 has a diameter of in a range of 0.0625″ to 0.25″. In some embodiments, each edge purge channel 150 has a diameter of 0.125″.

In one or more embodiments, each channel of the plurality of edge purge channels 250 is substantially coplanar with the top surface 220 or the bottom surface of the circular body 210. In other embodiments, each channel of the plurality of edge purge channels 250 is not substantially coplanar with either the top surface 220 or the bottom surface 230 of the circular body 210. As used in this regard, “substantially coplanar” means that each channel 250 is in the same plane as the top surface 220 or the bottom surface, or is within ±0.2 mm, ±0.15 mm, ±0.10 mm, or ±0.05 mm of the same plane. Stated differently, “substantially coplanar” means that the plurality of edge purge channels 250 are coplanar with the top surface 220 or the bottom surface within ±0.2 mm, ±0.15 mm, ±0.10 mm, or ±0.05 mm.

In some embodiments, the plurality of edge purge channels 250 meets the outer peripheral surface 240 at a right angle. In some embodiments, the plurality of edge purge channels 250 does not meet the outer peripheral surface 240 at a right angle.

In some embodiments, each channel 250 is closer to the top surface 220 than the bottom surface. In some embodiments, each channel 250 is closer to the bottom surface than the top surface 220. In some embodiments, the plurality of edge purge channels 250 is angled towards the top surface 220. In some embodiments, the plurality of edge purge channels 250 is angled towards the bottom surface.

In some embodiments, the plurality of edge purge channels 250 comprises in a range of 4 to 16 channels. In some embodiments, the number of channels 250 is 5, 6, 7, 8, 9, 10, 11, 12, 13, 14, or 15. In some embodiments, the number of channels 250 is 6.

Methods of forming base plates 200 (i.e., circular base plates) are described herein. The methods described herein advantageously exclude one or more of a diffusion bonding process or a lapping process. Without intending to be bound by theory, methods including one or more of a diffusion bonding process or a lapping process form base plates having decreased edge purge channel uniformity as compared base plates 200 formed by the methods described herein. Without intending to be bound by theory, methods including one or more of a diffusion bonding process or a lapping process form base plates having an increased amount of metal contamination as compared to base plates 200 formed by the methods described herein. In some embodiments, the base plate 200 has an atomic copper level of less than or equal to 10×10¹⁰ atom/cm².

Some embodiments of the disclosure relate to methods of forming a base plate 200 for a heater pedestal 100. In some embodiments, the methods comprise drilling a plurality of edge purge channels 250 into an outer peripheral surface 240 of the circular body 210. The plurality of edge purge channels 250 extend from the outer peripheral surface 240 to a common point 260 within the circular body 210. For the avoidance of doubt, while FIG. 2 shows a top view of the circular body 210, the plurality of edge purge channels 250 extend through the outer peripheral surface 240.

The drilling process may include any suitable drilling process known to the skilled artisan. In one or more embodiments, drilling comprises a gun drilling process. Without intending to be bound by any particular theory of operation, gun drilling is a deep hole drilling process that uses a long, thin cutting tool to produce linear holes with high depth-to-diameter ratios.

In operation, a gas (i.e., a purge gas) may be flowed from the common point 260 and through the plurality of edge purge channels 250. The purge gas flows through the plurality of edge purge channels 250 to the outer peripheral surface 240. The dashed arrow in FIG. 2 denotes the purge gas flowing from the common point 260 and through the plurality of edge purge channels 250 to the outer peripheral surface 240. In some embodiments, the purge gas flows through the plurality of edge purge channels 250 to a region surrounding the outer peripheral surface 240 of the base plate 200. In some embodiments, the purge gas comprises one or more of argon (Ar), helium (He) or nitrogen (N₂). In some embodiments, the purge gas comprises argon (Ar).

The inventors have surprisingly found that a gas flowed through the plurality of edge purge channels 250 formed by the disclosed methods has a flow non-uniformity at the outer peripheral surface 240 of less than or equal to about 20%. Without intending to be bound by theory, the flow non-uniformity found by the inventors has a low 3-sigma value. In one or more embodiments, the gas has a flow non-uniformity at the outer peripheral surface 240 of less than or equal to about 15%, less than or equal to about 10%, less than or equal to about 7.5%, less than or equal to about 5%, less than or equal to about 2%, or less than or equal to about 1%.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A base plate comprising:
a circular body having a top surface, a bottom surface, and an outer peripheral surface; and
a plurality of substantially linear edge purge channels within the circular body, each channel extending from the outer peripheral surface to a common point within the circular body,
wherein the base plate has an atomic copper level of less than or equal to 10×10¹⁰ atom/cm².

2. The base plate of claim 1, wherein the common point is within a region bounded by a circle with a radius of less than or equal to 15% of a total radius of the circular body.

3. The base plate of claim 2, wherein the common point is the center of the circular body.

4. The base plate of claim 1, wherein a gas flowed through the plurality of edge purge channels has a flow non-uniformity at the outer peripheral surface of less than or equal to about 20%.

5. The base plate of claim 1, wherein the plurality of edge purge channels comprises a number of channels in a range of 4 to 16 channels.

6. The base plate of claim 5, wherein the number of channels is six.

7. The base plate of claim 1, wherein a cross-section of one of the plurality of edge purge channels is circular.

8. The base plate of claim 7, wherein each edge purge channel has a diameter of in a range of 0.0625″ to 0.25″.

9. The base plate of claim 1, wherein each channel of the plurality of edge purge channels is substantially coplanar with the top surface or the bottom surface of the circular body.

10. The base plate of claim 1, wherein each channel of the plurality of edge purge channels is not substantially coplanar with the top surface or the bottom surface of the circular body.

11. A heater pedestal configured to support a substrate during processing, the heater pedestal comprising the base plate of claim 1.

12. A method of forming a base plate for a heater pedestal, the method comprising:
drilling a plurality of edge purge channels into an outer peripheral surface of a circular body of a base plate, the plurality of edge purge channels extending from the outer peripheral surface to a common point within the circular body.

13. The method of claim 12, wherein drilling comprises a gun drilling process.

14. The method of claim 12, wherein each edge purge channel has a diameter in a range of 0.0625″ to 0.25″.

15. The method of claim 12, wherein the common point is within a region bounded by a circle with a radius of less than or equal to 15% of a total radius of the circular body.

16. The method of claim 15, wherein the common point is the horizontal center of the circular body.

17. The method of claim 12, wherein the plurality of edge purge channels comprises a number of channels in a range of 4 to 16 channels.

18. The method of claim 17, wherein the number of channels is six.

19. The method of claim 12, wherein the method does not include a diffusion bonding process or a lapping process.

20. The method of claim 12, wherein the plurality of edge purge channels are substantially coplanar.
